(19) United States
(12) Patent Application Publication
(10) Pub. No.: US 2007/0176264 A1
(43) Pub. Date: Aug. 2, 2007

(54) Resistive random access memory device including an amorphous solid electrolyte layer

(76) Inventors: Jung-hyun Lee, Yongin-si (KR); Sang-jun Choi, Yongin-si (KR)

Correspondence Address: HARNESS, DICKEY & PIERCE, P.L.C., P.O. BOX 8910, RESTON, VA, 20195, US

(21) Appl. No.: 11/653,316

(22) Filed: Jan. 16, 2007

(30) Foreign Application Priority Data
Jan. 16, 2006 (KR) 10-2006-0004478

(51) Int. Cl. H01L 29/22

(52) U.S. Cl. 257/614

(57) ABSTRACT

Provided is a resistive memory device including an amorphous solid electrolyte layer in a storage node. The resistive memory device includes a switching device and a storage node connected to the switching device. The storage node includes upper and lower electrodes formed of a bivalent or multivalent metal, and an amorphous solid electrolyte layer and an ion source layer formed of a monovalent metal between the upper and lower electrodes.

### PRIORITY STATEMENT

This application claims the benefit of Korean Patent Application No. 10-2006-0004478, filed on Jan. 16, 2006, in the Korean Intellectual Property Office, the disclosure of which is incorporated herein in its entirety by reference.

### BACKGROUND

1. Field

Example embodiments relate to a semiconductor memory device, and, for example, to a non-volatile resistive random access memory (RRAM).

2. Description of the Related Art

In general, conventional resistive random access memories (RRAMs) contain a platinum (Pt) electrode and use a nickel oxide (NiO) film as a variable resistance layer. Many existing RRAMs have a current-voltage relationship as illustrated in FIG. 1.

FIG. 1 plots the characteristic current of a related art RRAM as a function of voltage. The area A1 of FIG. 1 illustrates rapidly-changing current across a relatively large voltage range. This current corresponds to rapidly-changing resistance in this same voltage range, since current and resistance in an electrical circuit are directly related.

This rapidly-changing current zone A1 marks the border of two different resistance states as shown by the two distinct current trends in the plot; however, the border at which the RRAM's variable resistance layer changes resistance states is excessively wide, as shown by the horizontal width of A1.

If resistance states of a related art RRAM's variable resistance layer change over an excessively wide range of voltages, as in FIG. 1, it is difficult to successfully reproduce or predict a resistance state change for any given voltage. Thus the variable resistance layer of the RRAM in FIG. 1 will have low reliability and predictability due to its wide voltage range of resistance change.

A related art RRAM with an additional storage node may solve the above-described problem common to related art RRAMs. As illustrated in FIG. 2, an additional storage node of the related art RRAM includes a lower electrode 10 formed of Cu, a upper electrode 20 formed of Pt, and a sulfide layer 30 (for example, a CuS layer) positioned between the lower electrode 10 and the upper electrode 20 that functions as the variable resistance layer.

FIG. 3 is a graph plotting the characteristic current as a function of voltage across such a related art RRAM with the additional storage node illustrated in FIG. 2. A2 in FIG. 3 illustrates a range of voltage with rapidly-changing current corresponding to resistance state change, similar to A1 in FIG. 1. A2 in FIG. 3, however, shows resistance change occurring over a much narrower range of voltages than that of A1 of FIG. 1. Thus the conventional RRAM with the additional storage node measured in FIG. 3 may solve the problem of a wide resistance change voltage range of the conventional RRAM measured in FIG. 1.

However, as integration increases and the size of the storage node decreases to sub-micron units, new problems occur. For example, when the size of the storage node illustrated in FIG. 2 is reduced to sub-micron units, an ion source (for example, Cu) of the lower electrode 10 forms on the interface between the upper electrode 20 and the sulfide layer 30. This may occur because the ion source of the lower electrode 10 diffuses through the grain boundaries of sulfide layer 30 due to the polycrystalline state of the sulfide layer 30.

When an ion source of the lower electrode 10 forms on the interface between the upper electrode 20 and the sulfide layer 30, the Cu layer/sulfide layer/Pt layer structure of the storage node in FIG. 2 changes to a Cu layer/sulfide layer/Cu layer structure. When this occurs, an effective metal bridge forms across the sulfide layer and differentiation between the upper and lower electrodes of the storage node may be reduced. Current flowing through the storage node with such a metal bridge may not be affected by the variable resistance sulfide layer and no resistance state change and drop in current at a particular voltage will be observed.

Further, when an ion source diffuses through the grain boundaries of the sulfide layer 30 as described above, it may do so in a non-uniform way. This may cause the number of grain boundaries of the sulfide layer 30 to vary in each memory cell. Ultimately the distribution of grain boundaries may not be identical in any memory cell, and the voltage required to induce a resistance state change may be different for each cell.

### SUMMARY

Example embodiments include a resistive random access memory (RRAM) with the characteristic resistance state change at a particular voltage of larger RRAMs, but instead potentially being the size of a nanometer unit and having identical voltages for resistance change across all cells.

Example embodiments are directed to a memory device including a switching device and a storage node connected to the switching device, the storage node further including an upper electrode and a lower electrode, and an amorphous solid electrolyte layer and ion source layer formed between the upper electrode and the lower electrode.

Example embodiments are directed to a storage node, the storage node including an upper electrode and a lower electrode, and an amorphous solid electrolyte layer and ion source layer formed between the upper electrode and the lower electrode.

According to example embodiments, the amorphous solid electrolyte layer may include an oxide insulator.

According to example embodiments, the amorphous solid electrolyte layer may include a compound of a bivalent metal and sulfur (S), selenium (Se), or tellurium (Te).

According to example embodiments, the ion source layer may be formed of a monovalent metal.

According to example embodiments, the upper electrode may be formed of a bivalent metal and the lower electrode may be formed of a multivalent metal.

Example embodiments may further include a bivalent nitride layer or a multivalent nitride layer between the lower electrode and the amorphous solid electrolyte layer.

### BRIEF DESCRIPTION OF THE DRAWINGS

Those features described above and other features and advantages of example embodiments will become more apparent by describing in detail example embodiments thereof with reference to the attached drawings in which:

FIG. 1 is a graph plotting the typical current as a function of voltage of related art resistive random access memory (RRAM) devices including a NiO film as a variable resistance layer;

FIG. 2 is a cross-sectional view of a storage node included in a related art RRAM device including a sulfide film as a variable resistance layer;

FIG. 3 is a graph plotting the typical current as a function of voltage of the related art RRAM device including the storage node illustrated in FIG. 2;

FIG. 4 is a cross-sectional view of a storage node included in a RRAM device, according to an example embodiment; and

FIG. 5 is a cross-sectional view of a RRAM device including the storage node illustrated in FIG. 4, according to an example embodiment.

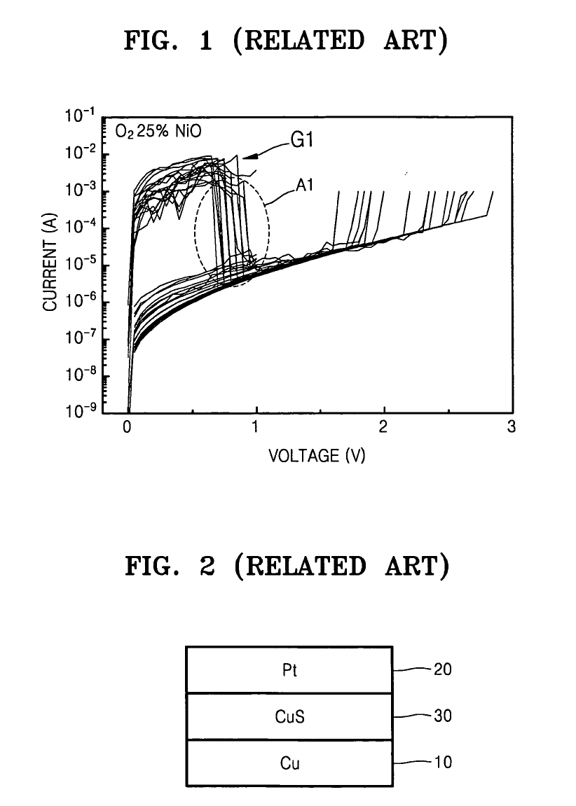

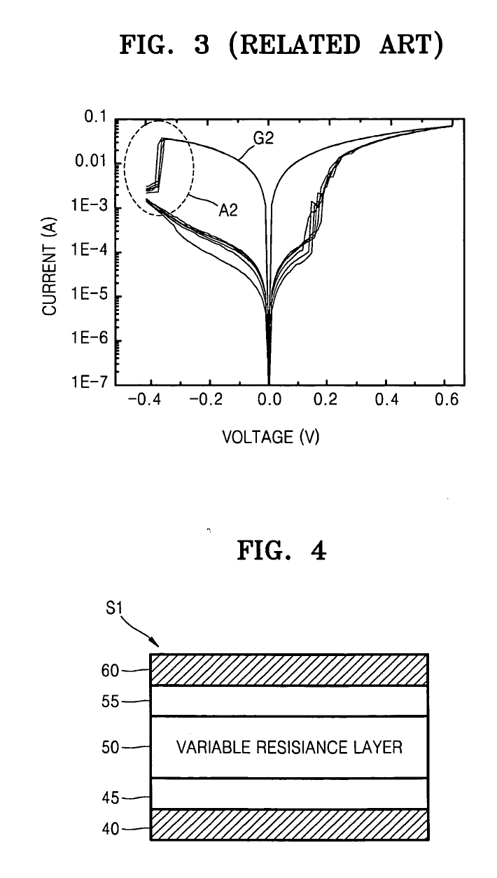

### DETAILED DESCRIPTION

Various example embodiments will now be described more fully with reference to the accompanying drawings in which some example embodiments are shown. In the drawings, the thicknesses of layers and regions are exaggerated for clarity.

Detailed illustrative embodiments are disclosed herein. However, specific structural and functional details disclosed herein are merely representative for purposes of describing example embodiments. This invention may, however, may be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element or layer is referred to as being “formed on” another element or layer, it can be directly or indirectly formed on the other element or layer. That is, for example, intervening elements or layers may be present. In contrast, when an element or layer is referred to as being “directly formed on” to another element, there are no intervening elements or layers present. Other words used to describe the relationship between elements or layers should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the FIGS. For example, two FIGS. shown in succession may in fact be executed substantially concurrently or may sometimes be executed in the reverse order, depending upon the functionality/acts involved.

Hereinafter, a resistive random access memory (RRAM) device including an amorphous solid electrolyte layer in a storage node, according to example embodiments, will be described in detail with reference to the appended drawings. In the drawings, the thicknesses of layers and regions are exaggerated for clarity.

FIG. 4 is a cross-sectional view of a storage node S1 included in a resistive random access memory (RRAM) device, according to an example embodiment.

Referring to FIG. 4, the storage node S1 of the RRAM device may include a lower electrode 40, a multivalent material layer 45, an amorphous solid electrolyte layer 50, an ion source layer 55, and/or an upper electrode 60 that may be stacked in the order as given. The lower electrode 40 may include a multivalent metal and the upper electrode 60 may include a bivalent metal. These layers may reduce or prevent diffusion between the lower and upper electrodes 40 and 60. The multivalent material layer 45 may include a bivalent nitride or a multivalent nitride layer. The amorphous solid electrolyte layer 50 may be an oxide insulator, for example, AlOₓ, WO₃, or the like. Also, the amorphous solid electrolyte layer 50 may include a bivalent metal and any one of sulfur (S), selenium (Se), or tellurium (Te). The ion source layer 55 may include a monovalent metal layer, for example, a Cu, Ag, Li layer or the like. The amorphous solid electrolyte layer 50 may function as a variable resistance layer.

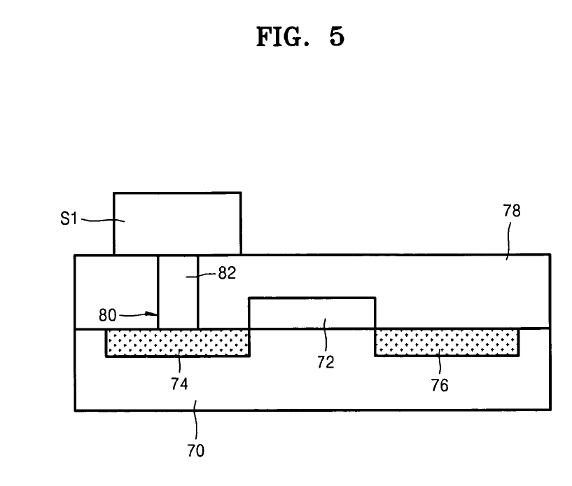

FIG. 5 is a cross-sectional view of a RRAM device including the storage node S1 illustrated in FIG. 4, according to an example embodiment.

Referring to FIG. 5, a gate 72 may be provided on a substrate 70, and first and second impurity regions 74 and 76 may be on both sides of the gate 72 in the substrate 70. One of the impurity regions 74 and 76 may act as a source and the other may act as a drain. The gate 72 and the impurity regions 74 and 76 may constitute a transistor. An insulating interlayer 78 may be formed on the substrate 70 to cover the transistor. A contact hole 80 may be formed in the insulating interlayer 78 so as to expose the first impurity region 74. The contact hole 80 may be filled with a conductive plug 82. A storage node S1 may be formed on the insulating interlayer 78 to cover an exposed part of the conductive plug 82.

Other example embodiments may include of a pad conductive layer to cover the conductive material 82 and a connection may be further formed between the storage node S1 and the insulating interlayer 78. The connection may be a conductive plug to electrically connect the pad conductive layer with the lower electrode 40 of the storage node S1.

As described above, the RRAM device according in example embodiments may include an amorphous solid electrolyte layer as a variable resistance layer and/or an ion source layer formed of a monovalent metal. Also, the RRAM device may include upper and lower electrodes formed of a bivalent or multivalent metal in order to reduce or prevent diffusion between the electrodes. Therefore, according to example embodiments, although the size of the storage node may be at the order of nanometers, ion diffusion may be reduced or prevented by the amorphous solid electrolyte layer 50, thereby reducing or preventing a current passing unaffected through the storage node. Also, according to example embodiments, because the solid electrolyte layer 50 may be in an amorphous state, it is likely that fewer or no grain boundaries exist in the solid electrolyte layer 50. Therefore, the number of grain boundaries will vary less from cell to cell, and the voltage required to induce a resistance state change may be suitably similar or identical for each cell.

While the example embodiments have been particularly shown and described with reference to example embodiments thereof, it will be understood by those of ordinary skill in the art that various changes in form and details may be made therein without departing from the spirit and scope of example embodiments as defined by the following claims.

What is claimed is:

1. A storage node comprising:
two electrodes; and
an amorphous solid electrolyte layer between the two electrodes; and
an ion source layer between one of the two electrodes and the amorphous solid electrolyte layer.

2. The storage node of claim 1, wherein the amorphous solid electrolyte layer includes an oxide insulator.

3. The storage node of claim 1, wherein the amorphous solid electrolyte layer includes a bivalent metal and an element selected from the group consisting of sulfur (S), selenium (Se), and tellurium (Te).

4. The storage node of claim 1, wherein the ion source layer is formed of a monovalent metal.

5. The storage node of claim 1, wherein one of the two electrodes includes a bivalent metal and the other of the two electrodes includes a multivalent metal.

6. The storage node of claim 5, further comprising a nitride layer between the electrode including the bivalent metal and the amorphous solid electrolyte layer.

7. The storage node of claim 6, wherein the nitride layer includes a multivalent nitride layer.

8. The storage node of claim 5, wherein the multivalent metal layer includes a bivalent nitride layer.

9. The storage node of claim 5, wherein the ion source layer is between the electrode including the multivalent metal and the amorphous solid electrolyte layer.

10. The storage node of claim 8, where in the ion source layer is formed of a monovalent metal.

11. The storage node of claim 1, further comprising a nitride layer between one of the two electrodes and the amorphous solid electrolyte layer.

12. The storage node of claim 11, wherein the nitride layer includes a multivalent nitride layer.

13. The storage node of claim 11, wherein the multivalent nitride layer includes a bivalent nitride layer.

14. A memory device comprising
a switching device; and
the storage node of claim 1.
